(19) United States
(12) Patent Application Publication
(10) Pub. No.: US 2011/0084755 A1
(43) Pub. Date: Apr. 14, 2011

(54) ANALOG SWITCH

(76) Inventors: Yoshitsugu Inagaki, Kyoto (JP); Koji Oka, Osaka (JP); Toshiaki Ozeki, Osaka (JP); Takeshi Okumoto, Hyogo (JP)

(21) Appl. No.: 12/971,510

(22) Filed: Dec. 17, 2010

Related U.S. Application Data
(63) Continuation of application No. PCT/JP2009/002409, filed on Jun. 1, 2009.

(30) Foreign Application Priority Data
Jun. 19, 2008 (JP) 2008-160616

(51) Int. Cl. H03K 17/687

(52) U.S. Cl. 327/427

(57) ABSTRACT

An analog switch (100) of the present invention is characterized by being constructed by MOS transistors and comprising a switch (102) connecting an input terminal VIN(104) and the substrate voltage of the NMOS transistor (101), a switch (103), being operated in a reverse phase to that of the switch (102), connecting the substrate voltage of the NMOS transistor(101) and the ground (VSS), and a voltage follower circuit (106) which, having a high input impedance and being connected between the input terminal (104) and the switch (102), suppresses the flow of the input current from the input terminal (104). According to the present invention, in an analog switch which is constituted by MOS transistors, it is possible to suppress that the input current flows into the substrate when the analog switch repeats the ON state and the OFF state.

### TECHNICAL FIELD

The present invention relates to an analog switch which is used in an analog circuit such as a analog/digital converter or a switched capacitor.

### BACKGROUND ART

An conventional analog switch is configured to have a switch connecting an analog switch input and a substrate of a MOS transistor constituting the analog switch so as to reduce the influences of the substrate bias in the ON state while have a switch connecting the substrate of the MOS transistor constituting the analog switch to ground in the OFF state, where these switches are operated in reverse phases to each other.

It is configured that the electric charges which are charged by the input current flowing from an analog switch input into the parasitic capacitance which is parasite to the substrate constituting the analog switch in the ON state of the analog switch are discharged to the substrate voltage, in this case, the ground when the switch has become the OFF state.

Therefore, the input current value depends on in what state the analog switch is, i.e., the frequency of repeating the ON state and OFF state, and when the frequency is increased, the input current increases while the frequency is lowered, the input current decreases.

Therefore, it may occur that the input impedance of the analog switch increases dependent on the frequency, thereby causing deterioration of characteristics of the circuit connected to this analog switch.

Accordingly, the circuit which is connected to this analog switch is required to be provided with a design which has paid considerations on the deterioration of the circuit characteristics due to the input current flowing into the substrate, whereby the difficulty in design has become quite high. (Patent Document 1) Japanese published patent publication

### DISCLOSURE OF THE INVENTION

### Problems to be Solved by the Invention

As one having a prior art construction, for example, there is one which has lowered the ON resistance of the analog switch by adjusting the substrate voltage of the MOS transistor constituting the analog switch, thereby intentionally having reduced the distortion in the input signal.

On the basis of the patent document 1, the prior art will be described.

It is configured that the drain voltage of the NMOS transistor 1 which is serially connected to the source of the NMOS transistor whose drain is connected to the gate terminal Φ of the NMOS transistor constituting the switch shown in FIG. 6 is connected to the substrate voltage of the NMOS transistor 1, and further that when the gate Φ of the NMOS transistor 1 is at VDD, i.e., during ON period, the voltage that is obtained by being divided by the NMOS transistors 5 and 6 is supplied to the substrate of the NMOS transistor 1. In other words, since the substrate voltage is high in the state of the switch being in ON state, it is possible to suppress the rise of the threshold voltage of the NMOS transistor 1 due to the substrate bias effect. While the rise of the ON resistance of the switch is thus suppressed, thereby the distortion of the signal is reduced, due to the construction in which a current normally flows from the power supply to the ground at a portion where the substrate voltage of the NMOS transistor 1 is generated, and further due to noises which are caused by the switching of the switch, the deterioration of the circuit characteristics are afraid of.

In consideration of the above, the present invention is directed to solving the above-described problems and to obtaining an analog switch which, being constructed by MOS transistors, can suppress that the input current flows into the substrate when the analog switch repeats the ON state and OFF state.

### Means to Solve the Problems

In order to solve the above-described problems, according to an analog switch of the present invention, there is provided an analog switch comprising an analog switch input terminal for inputting an analog signal, a MOS transistor for turning on or off the analog signal inputted to the analog switch input terminal, a first switch for connecting the analog switch input terminal and the substrate voltage of the MOS transistor, a second switch for connecting the substrate voltage of the MOS transistor and ground, the second switch operating in a phase reverse to that of the first switch, and a suppressing circuit which, having a high impedance as its input impedance and being connected between the analog switch input terminal and the first switch, suppresses a flow of a current inputted from the input terminal.

In addition, an analog circuit of the present invention is characterized in that the suppressing circuit is a voltage follower circuit.

In addition, an analog circuit of the present invention is characterized in that the suppressing circuit is a source follower circuit.

In addition, the analog circuit of the present invention is characterized in that the source follower circuit includes a level shift circuit for level shifting the output of the source follower circuit, and the first switch is connected to the output of the level shift circuit.

In addition, an analog circuit of the present invention is characterized in that the suppressing circuit is a voltage mirror circuit.

In addition, a sample hold circuit of the present invention is characterized in that it employs the above-described analog switch as an input switch.

### Effects of the Invention

According to the analog switch of the present invention, since it includes an analog switch input terminal for inputting an analog signal, a MOS transistor for turning on or off the analog signal inputted to the analog switch input terminal, a first switch for connecting the analog switch input terminal and the substrate voltage of the MOS transistor, a second switch for connecting the substrate voltage of the MOS transistor and ground, the second switch operating in a phase reverse to that of the first switch, and a suppressing circuit which has a high impedance as its input impedance, is connected between the analog switch input terminal and the first switch, and suppresses a flow of a current flowing into from the input terminal, it is possible to realize a low ON resistance as well as suppress the input current flowing from the analog switch input terminal from flowing into the substrate. As a result, designing of a circuit which is connected to the analog circuit, or designing of a circuit that is formed on the same substrate as the analog switch can be eased.

In addition, it is possible to prevent deteriorations of characteristics of the circuit formed on the substrate as the analog switch by having configured such that the flow of input current from the analog switch input terminal is suppressed so that no current flows to ground when being in an OFF state.

In addition, according to the analog switch of the present invention, since a voltage follower circuit is employed as the suppressing circuit, the input signal and the substrate voltage of the NMOS transistor can be made the same voltages, thereby the distortion of the analog switch can be effectively reduced.

In addition, according to the analog switch of the present invention, since a source follower circuit is employed as the suppressing circuit, an increase in the circuit scale can be suppressed.

In addition, according to the analog switch of the present invention, since a source follower circuit which includes a level shift circuit which is connected to the first switch is employed as the suppressing circuit, the difference between the voltage that is applied to the analog switch input terminal when in the ON state and the substrate voltage of the MOS transistor can be reduced.

In addition, according to the analog switch of the present invention, since a voltage mirror circuit is employed as the suppressing circuit, the difference between the voltage that is applied to the analog switch input terminal when in the ON state and the substrate voltage of the MOS transistor can be reduced.

In addition, according to the sample hold circuit of the present invention, since the analog switch is employed as an input switch, the deteriorations of the circuit characteristics which are caused by the input current of the analog switch can be prevented. As a result, when employing a sampling signal which is obtained by sample holding the signal from the analog switch in such as a video signal processing that employs an A/D converter, the generation of video noises is prevented.

### BRIEF DESCRIPTION OF DRAWINGS

FIG. 1 is a diagram illustrating a construction of an analog switch according to a first embodiment of the present invention.

FIG. 2 is a diagram illustrating ON/OFF timings of the analog switch according to the first embodiment of the present invention.

FIG. 3 is a diagram illustrating a construction of an analog switch according to a second embodiment of the present invention.

FIG. 4 is a diagram illustrating a construction of an analog switch according to a third embodiment of the present invention.

FIG. 5 is a diagram illustrating a construction of an analog switch according to a fourth embodiment of the present invention.

FIG. 6 is a diagram illustrating a construction of a prior art analog switch.

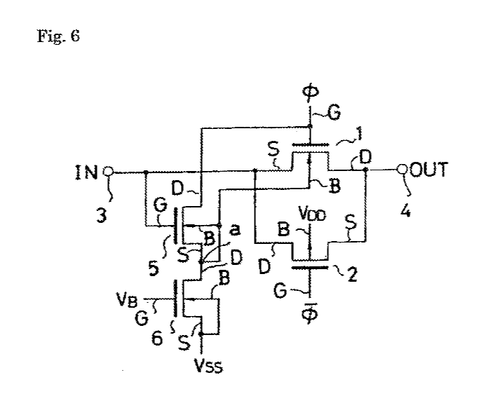

### BEST MODES EMBODYING THE INVENTION

Hereinafter, embodiments of the present invention will be described with reference to the drawings.

### Embodiment 1

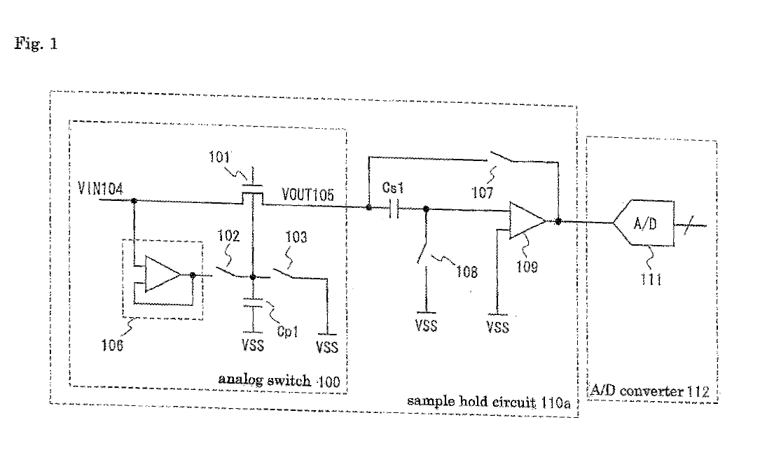

FIG. 1 is a diagram illustrating a construction of an analog switch according to a first embodiment of the present invention.

The analog switch 100 shown in FIG. 1 includes a NMOS transistor 101, the input terminal VIN104, the output terminal VOUT105, a suppressing circuit which has a high input impedance and suppresses a flow of a current inputted from the input terminal VIN104, a first switch 102 for connecting the output of the suppressing circuit and the substrate voltage of the NMOS transistor 101, and a second switch 103 for connecting the substrate voltage of the NMOS transistor 101 and the ground VSS.

The NMOS transistor 101 is one which turns ON or OFF the analog signal which is inputted from the input terminal VIN104, whose drain (or source) is connected to the output terminal VOUT105, and the gate thereof serves as an input terminal for the switch signal for turning ON or OFF the analog switch 100. In addition, the switch 102 is connected between the output of the suppressing circuit and the substrate voltage of the NMOS transistor 101, and the switch 103 is connected between the substrate voltage of the NMOS transistor 101 and ground (VSS). There is generated a parasitic capacitance Cp1 between the substrate voltage of the NMOS transistor 101 and ground (VSS). In addition, the switch 102 and the switch 103 are operated mutually in phases reverse to each other. As the suppressing circuit, the analog switch 100 shown in FIG. 1 is provided with a voltage follower circuit 106. The voltage follower circuit 106 is constituted by, for example, an operational amplifier.

In this first embodiment, a case where the analog switch 100 is employed as an input switch of the sample hold circuit and the sample hold circuit is connected to an A/D converter will be described.

In FIG. 1, the analog switch 100 is included in the sample hold circuit 110a and the output of the sample hold circuit 110a is outputted to the A/D converter 112.

The sample hold circuit 110a includes an analog switch 190, a sampling capacitance Cs1, a switch 107, a switch 108, and a buffer amplifier 109.

In FIG. 1, the sampling capacitance Cs1 has an end connected to the output terminal VOUT of the analog switch 100 and another end connected to one input of the buffer amplifier 109. The other input of the buffer amplifier 109 is connected to ground (VSS), and the switch 107 is connected between one end of the sampling capacitance Cs1 and the output of the buffer amplifier 109. The switch 108 is connected between the other end of the sampling capacitance Cs1 and the ground (VSS).

In addition, the A/D converter 112 is constituted similarly to that of the prior art example, and it has an A/D converter 111.

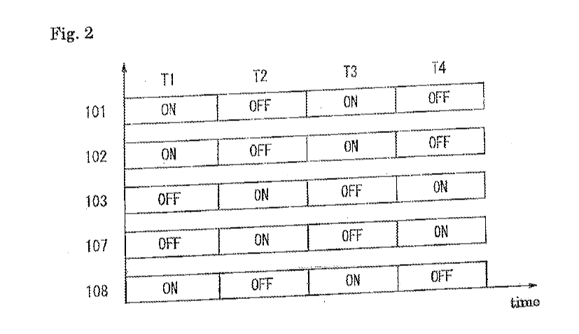

An operation of the sample hold circuit 100a having an analog switch 100 constructed as described above will be described with reference to FIG. 2.

FIG. 2 is a diagram illustrating ON/OFF timings of the NMOS transistor 101, switch 102, switch 103, switch 107, and switch 108, respectively.

As shown in FIG. 2, the switch 102 and the switch 108 are operated in the same phases as that of the NMOS transistor 101, and the switch 103 and the switch 107 are operated in the phases reverse to that of the NMOS transistor 101.

At first, at timing T1, a switch signal of “H” level is inputted to the gate of the NMOS transistor 101 by a not-shown signal source, thereby the analog switch 100 is turned ON. Then, the NMOS transistor 101 and the switch 102 are ON and the switch 103 is OFF, thereby the signal inputted from the input terminal VIN104 is outputted from the output terminal VOUT105. In addition, at timing T1, the switch 107 is turned OFF while the switch 108 is turned ON, thereby the input signal from the analog switch 100 is sampled by the sampling capacitance Cs1 and the buffer amplifier 109, to hold the sampled signal.

At this timing T1, a current from the input terminal VIN104 tends to flow into toward the parasitic capacitance Cp1 attached between the substrate voltage of the NMOS transistor 101 and the ground (VSS). However, since a voltage follower circuit 106 which has quite a high (approximately equal to infinite) input impedance is connected between the input terminal VIN104 and the switch 102, no current would flow into the parasitic capacitance Cpl which is connected to the substrate voltage of the NMOS transistor 101.

Next, at timing T2, a switch signal of “L” level is inputted to the gate of the NMOS transistor 101 by a not-shown signal source, thereby the analog switch 100 is turned OFF. Then, the NMOS transistor 101 and the switch 102 are in OFF states while the switch 103 is in ON state, and the switch 107 is turned ON while the switch 108 is turned OFF. In addition, at timing T2, the signal which was held in the sample hold circuit 110a at timing T1 is outputted to the A/D converter 111 of the A/D converter circuit 112, thereby performing an A/D conversion.

At this timing T2, since the substrate voltage is applied to the NMOS transistor 101 in the same phase as the input signal that is inputted from the input terminal VIN104 by the voltage follower circuit 106, it may not occur that the input current from the input terminal VIN104 is discharged toward the ground VSS by the application of the substrate voltage.

In other words, even when the analog switch 100 is turned OFF, since almost no charges are held in the parasitic capacitance Cpl which is connected to the substrate voltage of the NMOS transistor 101, it may not occur that the input current from the input terminal VIN104 is discharged toward the ground VSS.

Therefore, even if turning ON and OFF operations of the analog switch 100 are repeated, the charging of the input current from the input terminal VIN104 to the parasitic capacitance Cp1 and the discharging of the current from the parasitic capacitance Cp1 to ground VSS can be suppressed.

As described above, according to the analog switch 100 of this first embodiment, by providing a voltage follower circuit 106 having quite a high input impedance between the input terminal VIN104 and the switch 102, it is possible to suppress the input current inputted from the input terminal VIN104 from flowing into the substrate. As a result, when designing a circuit which is connected to the analog switch 100 or a circuit which is mounted on the same substrate as the analog switch 100 (here, a sample hold circuit), there is no necessity of considering influences by the input current, thereby easing the circuit design.

In addition, according to the analog switch 100 of this first embodiment, by configuring such that the input current from the input terminal VIN104 is suppressed in its ON state while no current is discharged to ground VSS in its OFF state, the deterioration of characteristics of the circuit which is disposed on the same substrate and has the common ground voltage as the analog switch 100 can be suppressed.

In addition, according to the sample hold circuit 100a of this first embodiment, by employing the analog switch 100 as an input switch, it is possible to prevent the deterioration of the circuit characteristics which may occur caused by the input current of the analog switch 100. As a result, when employing a sampling signal which is obtained by sampling the signal from the analog switch 100 by the sample hold circuit 110a in such as a video signal processing that employs an A/D converter circuit 112, the generation of video noises can be prevented.

In addition, by using the voltage follower circuit 106 as a suppressing circuit for suppressing the flow of input current inputted from the input terminal VIN104, the input signal and the substrate voltage of the NMOS transistor 101 can be made the same voltages, resulting in largely reducing distortions of the analog switch 100.

### Embodiment 2

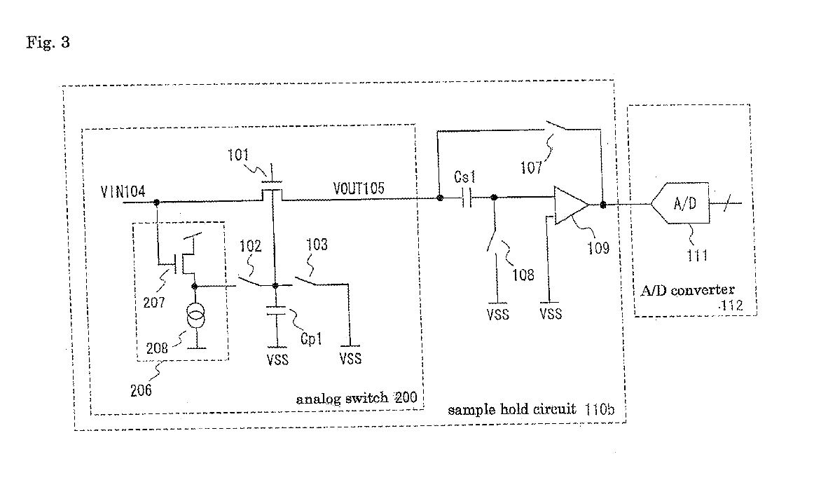

An analog switch according to a second embodiment of the present invention will be described as follows. FIG. 3 is a diagram illustrating a construction of an analog switch 200 according to a second embodiment of the present invention.

In FIG. 3, the analog switch 200 is included in the sample hold circuit 110b, and the output of the sample hold circuit 110b is connected to the A/D converter circuit 112.

The analog switch 200 of this second embodiment includes a source follower circuit 206 between the input terminal VIN104 and the switch 102 as a suppressing circuit for suppressing the flow of the input current from the input terminal VIN104. The other construction is the same as that of the analog switch 100. In addition, the sample hold circuit 110b has the same construction as the sample hold circuit 100a other than the construction of the analog switch 200.

In FIG. 3, the source follower circuit 206 is constituted by a NMOS transistor 207 and a current source circuit 208 which are mutually serially connected between the power supply and ground. The NMOS transistor 207 has a source (or drain) connected to power supply, and a gate terminal connected to the input terminal VIN104. The current source circuit 208 is connected between the drain (or source) of the NMOS transistor 207 and ground, and an end of the switch 102 is connected to the connection node between the NMOS transistor 207 and the current source circuit 208. The input impedance of the source follower circuit 206 is quite high (approximately equal to infinite) because the input thereof is provided by the gate terminal of the NMOS transistor 207.

An operation of the sample hold circuit 110b having the analog switch 200 which is thus constituted will be described as follows.

At first, at timing T1, a switch signal of “H” level is inputted to the gate of the NMOS transistor 101 by a not-shown signal source, thereby the analog switch 200 is turned. Then, the NMOS transistor 101 and the switch 102 are in ON states while the switch 103 is in OFF state, thereby the signal inputted from the input terminal VIN104 is outputted from the output terminal VOUT105. In addition, at timing T1, the switch 107 is turned OFF while the switch 108 is turned ON, thereby the input signal from the analog switch 100 is sampled by the sampling capacitance Cs1 and the buffer amplifier 109, to hold the sampled signal.

At this timing T1, a current from the input terminal VIN104 tends to flow into toward the parasitic capacitance Cp1 attached between the substrate voltage of the NMOS transistor 101 and the ground (VSS). However, since a source follower circuit 206 which has quite a high (approximately equal to infinite) input impedance is connected between the input terminal VIN104 and the switch 102, no current would flow into the parasitic capacitance Cp1 which is connected to the substrate voltage of the NMOS transistor 101.

Next, at timing T2, a switch signal of “L” level is inputted to the gate of the NMOS transistor 101 by a not-shown signal source, thereby the analog switch 200 is turned OFF. Then, the NMOS transistor 101 and the switch 102 are in OFF states while the switch 103 is in OFF state, and the switch 107 is turned ON while the switch 108 is turned OFF. In addition, at timing T2, the signal which was held in the sample hold circuit 110b at timing T1 is outputted to the A/D converter 111 of the A/D converter circuit 112, thereby performing an A/D conversion.

At this timing T2, since the substrate voltage is applied to the NMOS transistor 101 in the same phase as the input signal that is inputted from the input terminal VIN104 by the source follower circuit 206, it may not occur that the input current from the input terminal VIN104 is discharged toward the ground VSS by the application of the substrate voltage.

In other words, even when the analog switch 200 is turned OFF, since almost no charges are held in the parasitic capacitance Cp1 which is connected to the substrate voltage of the NMOS transistor 101, it may not occur that the input current from the input terminal VIN104 is discharged toward the ground VSS.

Therefore, even if turning ON and OFF operations of the analog switch 200 are repeated, the charging of the input current from the input terminal VIN104 to the parasitic capacitance Cp1 and the discharging of the current from the parasitic capacitance Cp1 to ground VSS can be suppressed.

As described above, according to the analog switch 200 of this second embodiment, by providing a source follower circuit 206 having quite a high input impedance between the input terminal VIN104 and the switch 102, it is possible to suppress the input current inputted from the input terminal VIN104 from flowing into the substrate. As a result, when designing a circuit which is connected to the analog switch 200 or a circuit which are mounted on the same substrate as the analog switch 200, there is no necessity of considering influences by the input current, thereby easing the circuit design.

In addition, according to the analog switch 200 of this second embodiment, by configuring such that the input current inputted from the input terminal VIN104 is suppressed in its ON state while no current is discharged to ground VSS in its OFF state, the deterioration of characteristics of the circuit which is disposed on the same substrate and has the common ground voltage as the analog switch 200 can be suppressed.

In addition, by employing the source follower circuit 206 as a suppressing circuit for suppressing the flow of input current from the input terminal VIN104, the circuit scale of the analog switch can be decreased, thereby eliminating the cost.

In addition, while in this second embodiment the source follower circuit 206 is constituted by an NMOS transistor and a current source circuit, the source follower circuit of an analog switch according to the present invention should not be limited thereto. For example, those constructed by employing PMOS transistors may be used.

### Embodiment 3

An analog switch according to a third embodiment of the present invention will be described as follows.

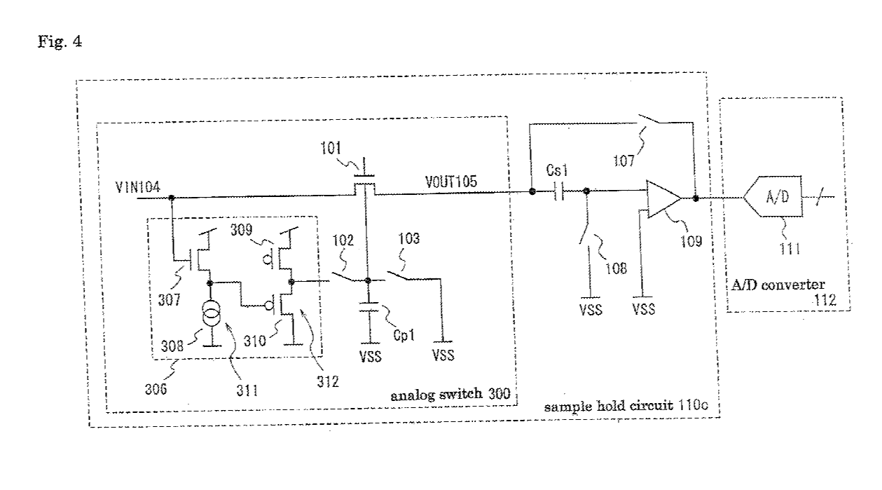

FIG. 4 is a diagram illustrating a construction of an analog switch 300 according to a third embodiment of the present invention. In FIG. 4, the analog switch 300 is included in the sample hold circuit 110c, and the output of the sample hold circuit 110c is connected to the A/D converter circuit 112.

The analog switch 300 of this third embodiment includes a source follower circuit 306 between the input terminal VIN104 and the switch 102 as a suppressing circuit for suppressing the flow of input current inputted from the input terminal VIN104. The other construction is the same as that of the analog switch 200. In addition, the sample hold circuit 110c has the same construction as the sample hold circuit 100a other than the construction of the analog switch 300.

In FIG. 4, the source follower circuit 306 is constituted by a NMOS transistor 307 and a current source circuit 308 which are mutually serially connected between power supply and ground, and a PMOS transistor 309 and a PMOS transistor 310 which are mutually serially connected between power supply and ground. Here, the PMOS transistor 309 and the PMOS transistor 310 constitute a level shift circuit 312 which level shifts the output of the source follower circuit body 311 comprising the NMOS transistor 307 and the current source circuit 308.

The NMOS transistor 307 has a drain (or source) connected to power supply, a gate terminal connected to the input terminal VIN104, and a source (or drain) connected to ground via the current source circuit 308. The PMOS transistor 309 has a source (or drain) connected to power supply and a gate terminal connected to a not-shown predetermined voltage to constitute a current source circuit. The PMOS transistor 310 has a source (or drain) connected to the drain (or source) of the PMOS transistor 309, a gate connected to the connection node of the NMOS transistor 307 and the current source circuit 308, and a drain (or source) connected to ground. An end of the switch 102 is connected to the connection node of these PMOS transistor 309 and the PMOS transistor 310. The input impedance of the source follower circuit 306 is quite high (approximately equal to infinite) since the input thereof is provided by the gate terminal of the NMOS transistor 307.

An operation of the sample hold circuit 110c having the analog switch 300 which is thus constituted will be described as follows.

At first, at timing T1, a switch signal of “H” level is inputted to the gate of the NMOS transistor 101 by a not-shown signal source, thereby the analog switch 300 is turned ON. Then, the NMOS transistor 101 and the switch 102 are in ON states while the switch 103 is in OFF state, thereby the input signal inputted from the input terminal VIN104 is outputted from the output terminal VOUT105. In addition, at timing T1, the switch 108 is turned ON, thereby the input signal from the analog switch 100 is sampled by the sampling capacitance Cs1 and the buffer amplifier 109, to hold the sampled signal.

At this timing T1, a current from the input terminal VIN104 tends to flow into toward the parasitic capacitance Cp1 attached between the substrate voltage of the NMOS transistor 101 and the ground (VSS). However, since a source follower circuit 306 which has quite a high (approximately equal to infinite) input impedance is connected between the input terminal VIN104 and the switch 102, no input current would flow into the parasitic capacitance Cp1 which is connected to the substrate voltage of the NMOS transistor 101.

Next, at timing T2, a switch signal of “L” level is inputted to the gate of the NMOS transistor 101 by a not-shown signal source, thereby the analog switch 300 is turned OFF. Then, the NMOS transistor 101 and the switch 102 are in OFF states while the switch 103 is in ON state, and the switch 107 is turned ON while the switch 108 is turned OFF. In addition, at timing T2, the signal which was held in the sample hold circuit 110c at timing T1 is outputted to the A/D converter 111 of the A/D converter circuit 112, thereby performing an A/D conversion.

At this timing T2, since the substrate voltage is applied to the NMOS transistor 101 in the same phase as the input signal that is inputted from the input terminal VIN104 by the source follower circuit 306, it may not occur that the input current from the input terminal VIN104 is discharged toward the ground VSS by the application of the substrate voltage.

In other words, even when the analog switch 300 is turned OFF, since almost no charges are held in the parasitic capacitance Cpl which is connected to the substrate voltage of the NMOS transistor 101, it may not occur that the input current from the input terminal VIN104 is discharged toward the ground VSS.

Therefore, even if turning ON and OFF operations of the analog switch 300 are repeated, the charging of the input current from the input terminal VIN104 to the parasitic capacitance Cp1 and the discharging of the current from the parasitic capacitance Cpl to ground VSS can be suppressed.

In addition, though in the analog switch 200 of the above-described second embodiment there may arise a problem that the difference between the voltage that is applied to the input terminal VIN104 and the substrate voltage of the NMOS transistor 101 when the analog switch 200 is in ON state becomes large by the reasons on a circuit construction due to that the source follower circuit 206 is employed as a suppressing circuit, in the analog switch 300 of this third embodiment, the above-described problem can be solved by that the source follower circuit 306 includes a level shift circuit which comprises a PMOS transistor 309 and a PMOS transistor 310 and is connected to the switch 102.

As described above, according to the analog switch 300 of this third embodiment, by providing a source follower circuit 306 having quite a high input impedance between the input terminal VIN104 and the switch 102, it is possible to suppress the input current inputted from the input terminal VIN104 from flowing into the substrate. As a result, when designing a circuit which is connected to the analog switch 300 or a circuit which is mounted on the same substrate as the analog switch 300, there is no necessity of considering influences by the input current, thereby easing the circuit design.

In addition, according to the analog switch 300 of this second embodiment, by configuring such that the input current inputted from the input terminal VIN104 is suppressed in its ON state while no current is discharged to ground VSS in its OFF state, the deterioration of characteristics of the circuit which is disposed on the same substrate and has the common ground voltage as the analog switch 300 can be prevented.

In addition, according to the analog switch 300 of this third embodiment, since the source follower circuit 306 has a level shift circuit 312 that is constituted by the PMOS transistor 309 and the PMOS transistor 310, the difference between the voltage that is applied to the input terminal VIN104 when the analog switch 300 is in ON state and the substrate voltage of the NMOS transistor 101 can be reduced, thereby suppressing the influences by the substrate bias effect.

### Embodiment 4

An analog switch according to a fourth embodiment of the present invention will be described as follows.

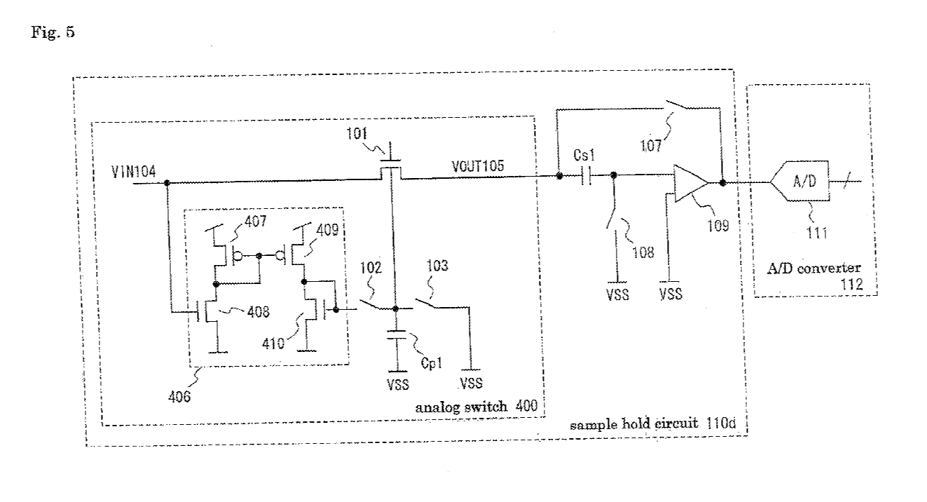

FIG. 5 is a diagram illustrating a construction of an analog switch 400 according to a fourth embodiment of the present invention.

In FIG. 5, the analog switch 400 is included in the sample hold circuit 110d, and the output of the sample hold circuit 110d is connected to the A/D converter circuit 112.

The analog switch 400 of this fourth embodiment includes a voltage mirror circuit 406 between the input terminal VIN104 and the switch 102 as a suppressing circuit for suppressing the flow of input current inputted from the input terminal VIN104. The other construction is the same as that of the analog switch 100. In addition, the sample hold circuit 110d has the same construction as the sample hold circuit 100a other than the construction of the analog switch 400.

In FIG. 5, the voltage mirror circuit 406 is constituted by four MOS transistors, i.e., a PMOS transistor 407 and an NMOS transistor 408 mutually serially connected between power supply and ground and a PMOS transistor 409 and a NMOS transistor 410 mutually serially connected between power supply and ground.

The PMOS transistor 407 has its source (or drain) connected to power supply and its gate connected to its drain (or source). The NMOS transistor 408 has its source (or drain) connected to the drain (or source) of the PMOS transistor 407, its gate connected to the input terminal VIN104, and its source (or drain) connected to ground. The PMOS transistor 409 has its source (or drain) connected to power supply and its gate connected to the gate of the PMOS transistor 407. The NMOS transistor 410 has its drain (or source) connected to its gate and an end of the switch 102, and has its source (or drain) connected to ground.

Since the input impedance of the voltage mirror circuit 406 is quite high (approximately equal to infinite) due to that an input thereof is provided by the gate of the NMOS transistor 408, it may not occur that a current inputted from the input terminal VIN104 flows into the parasitic capacitance connected to the substrate voltage of the NMOS transistor 101 even when the analog switch 400 is in an ON state. In addition, by constructing the voltage mirror circuit 406 by a PMOS transistor and a NMOS transistor as shown in FIG. 5, there arises almost no difference between the voltage that is applied to the input terminal VIN104 and the substrate voltage of the NMOS transistor 101.

An operation of the sample hold circuit 110d having the analog switch 400 which is thus constituted will be described as follows.

At first, at timing T1, a switch signal of “H” level is inputted to the gate of the NMOS transistor 101 by a not-shown signal source, thereby the analog switch 400 is turned ON. Then, the NMOS transistor 101 and the switch 102 are in ON states while the switch 103 is in OFF state, thereby the input signal inputted from the input terminal VIN104 is outputted from the output terminal VOUT105. In addition, at timing T1, the switch 107 is turned OFF while the switch 108 is turned ON, thereby the input signal from the analog switch 400 is sampled by the sampling capacitance Cs1 and the buffer amplifier 109, to hold the sampled signal.

At this timing T1, a current from the input terminal VIN104 tends to flow into toward the parasitic capacitance Cp1 attached between the substrate voltage of the NMOS transistor 101 and the ground (VSS). However, since a voltage mirror circuit 406 which has quite a high (approximately equal to infinite) input impedance is connected between the input terminal VIN104 and the switch 102, no input current would flow into the parasitic capacitance Cp1 which is connected to the substrate voltage of the NMOS transistor 101.

Next, at timing T2, a switch signal of “L” level is inputted to the gate of the NMOS transistor 101 by a not-shown signal source, thereby the analog switch 400 is turned OFF. Then, the NMOS transistor 101 and the switch 102 are in OFF states and the switch 103 is in OFF state, and the switch 107 is turned ON while the switch 108 is turned OFF. In addition, at timing T2, the signal which was held in the sample hold circuit 110d at timing T1 is outputted to the A/D converter 111 of the A/D converter circuit 112, thereby performing an A/D conversion.

At this timing T2, since the substrate voltage is applied to the NMOS transistor 101 in the same phase as the input signal that is inputted from the input terminal VIN104 by the voltage mirror circuit 406, it may not occur that the input current from the input terminal VIN104 is discharged toward the ground VSS by the application of the substrate voltage.

In other words, even when the analog switch 400 is turned OFF, since almost no charges are held in the parasitic capacitance Cp1 which is connected to the substrate voltage of the NMOS transistor 101, it may not occur that the input current from the input terminal VIN104 is discharged toward the ground VSS.

Therefore, even if turning ON and OFF operations of the analog switch 400 are repeated, the charging of the input current from the input terminal VIN104 to the parasitic. capacitance Cpl and the discharging of the current from the parasitic capacitance Cpl to ground VSS can be suppressed.

As described above, according to the analog switch 400 of this fourth embodiment, by providing a voltage mirror circuit 406 having quite a high input impedance between the input terminal VIN104 and the switch 102, it is possible to suppress the input current inputted from the input terminal VIN104 from flowing into the substrate. As a result, when designing a circuit which is connected to the analog switch 400 or a circuit which is mounted on the same substrate as the analog switch 400, there is no necessity of considering influences by the input current, thereby easing the circuit design.

In addition, according to the analog switch 400 of this fourth embodiment, by configuring such that the input current inputted input terminal VIN104 is suppressed in its ON state while no current is discharged to ground VSS in its OFF state, the deterioration of characteristics of the. circuit which is disposed on the same substrate and has the common ground voltage as the analog switch 400 can be prevented.

In addition, according to the analog switch 400 of this fourth embodiment, since the voltage mirror circuit 406 is employed as a suppressing circuit for suppressing the flow of the current inputted from the input terminal VIN104, the difference between the voltage that is applied to the input terminal VIN104 and the substrate voltage of the NMOS transistor 101 can be reduced, thereby suppressing the influences by the substrate bias effect.

While in the above-described first to fourth embodiments the outputs of the sample hold circuits 110a to 110d are handled by the A/D converter circuit 112, the circuit at a latter stage relative to the sample hold circuits is not limited to an A/D converter circuit. The circuits at a latter stage relative to the sample hold circuits 110a to 110d may be circuits other than the A/D converter circuit.

While in the above-described first to fourth embodiments there is provided an A/D converter circuit at a latter stage of the sample hold circuits 110a to 110d, the sample hold circuit may be included in the A/D converter circuit

In addition, while in the above-describe first to fourth embodiments no mention is particularly given of signals which turn ON or OFF the switches 102, 103 and switches 107, 108, these may be turned ON or OFF by signals which turn ON or OFF the NMOS transistors in the analog switch, or these may be turned ON or OFF by switch signals which are separately generated from those signals.

In addition, while the above-described first to fourth embodiments are described on cases where the sample hold circuit including an analog switch is of a single construction, the present invention can adopt a sample hold circuit of a differential construction and the same effects can be obtained.

### APPLICABILITY IN INDUSTRY

As described above, the analog switch of the present invention can suppress the input current which flows into the substrate even when the ON state and the OFF state are repeated at a high frequency, and therefore, it is very suitable for a semiconductor integrated circuit that requires a high precision and a high performance, for example, a semiconductor integrated circuit for a video apparatus or for a portable apparatus, and a system employing same.

### DESCRIPTION OF REFERENCE NUMERALS

100, 200, 300, 400 analog switch

101, 1, 5, 6 NMOS transistor

102, 103 switch

104 input terminal

105 output terminal

106 voltage follower circuit

110a, 110b, 110c, 110d sample hold circuit

206, 306 source follower circuit

207, 307, 408, 410 NMOS transistors

208, 308 current source circuit

309, 310, 407, 409 PMOS transistors

311 source follower circuit body

312 level shift circuit

406 voltage mirror circuit

Cp1, Cp5 parasitic capacitance

Cs1 sampling capacitance

Ichg analog switch input current

Idchg discharging current from the parasitic capacitance

What is claimed is:

1. An analog switch comprising:
an analog switch input terminal for inputting an analog signal;
a MOS transistor for turning on or off the analog signal inputted to the analog switch input terminal;
a first switch for connecting said analog switch input terminal and the substrate voltage of said MOS transistor;
a second switch for connecting the substrate voltage of said MOS transistor and ground, said second switch operating in a phase reverse to that of said first switch; and
a suppressing circuit which, having a high impedance as its input impedance and being connected between said analog switch input terminal and said first switch, and suppresses a flow of a current inputted from said input terminal.

2. An analog switch as defined in claim 1, wherein said suppressing circuit is a voltage follower circuit.

3. An analog switch as defined in claim 1, wherein said suppressing circuit is a source follower circuit.

4. An analog switch as defined in claim 3, wherein said source follower circuit includes a level shift circuit for level shifting the output of said source follower circuit, and said first switch is connected to the output of said level shift circuit.

5. An analog switch as defined in claim 1, wherein said suppressing circuit is a voltage mirror circuit.

6. A sample hold circuit which employs said analog switch as defined in claim 1 as an input switch.
